(19) United States
(12) Patent Application Publication
(10) Pub. No.: US 2015/0295033 A1
(43) Pub. Date: Oct. 15, 2015

(54) APPARATUS AND METHOD FOR MANUFACTURING SAME

(71) Applicant: PS5 Luxco S.a.r.l., Luxembourg (LU)

(72) Inventor: Mika Yoshida, Tokyo (JP)

(21) Appl. No.: 14/439,012

(22) PCT Filed: Nov. 22, 2013
(86) PCT No.: PCT/JP2013/081483

§ 371 Date: Apr. 28, 2015

(30) Foreign Application Priority Data
Nov. 30, 2012 (JP) 2012-262021

(51) Int. Cl. H01L 29/06; H01L 21/762; H01L 21/28; H01L 29/40

(52) U.S. Cl. CPC H01L 29/0653; H01L 29/408; H01L 21/76224; H01L 21/28017

(57) ABSTRACT

This apparatus is composed of an insulating film having a high dielectric constant and an electrode film including a metal material, layered in that order on a substrate divided into an active region and an element separation region surrounding the active region, and has a gate structure extending from the active region to the element separation region. The element separation region is provided with: a groove formed in the substrate; a first insulating film covering the side wall face of the groove and embedded in the bottom part of the groove; and a second insulating film covering the first insulating film embedded in the bottom part of the groove and embedded in the top part of the groove.

### TECHNICAL FIELD

The present invention relates to a semiconductor device and a method of manufacturing the same, and in particular relates to a semiconductor device containing transistors having an HKMG (high-k metal gate) construction, and a method of manufacturing the same.

### Background art

The HKMG construction has been proposed in order to resolve various problems that arise in conjunction with developments involving reductions in the power supply voltage, increases in the speed, and increases in the degree of integration of transistors.

With transistors having an HKMG construction it is known that the threshold shifts when the high dielectric-constant (high-k) gate insulating film being employed is exposed to oxygen (see patent literature article 1, for example).

Also, a method known as FCVD (flowable chemical vapor deposition) (see patent literature article 2, for example) is known as a method of forming insulating films in element isolation grooves, the aspect ratio of which is expected to rise yet further as transistors become more highly integrated.

### PATENT LITERATURE

Patent literature article 1: Japanese Patent Kokai 2010-536169

Patent literature article 2: Specification of US Patent Application Publication No. 2011/0081782

### SUMMARY OF THE INVENTION

### Problems to be Resolved by the Invention

The oxygen which causes a shift in the threshold of a transistor having an HKMG construction may even be supplied from oxides in contact with the high dielectric-constant gate insulating film.

For example, during the manufacture of a semiconductor device, if annealing is performed while the high dielectric-constant gate insulating film is in contact with a silicon dioxide film filling an STI (shallow trench isolation) defining an active region, oxygen is supplied from the silicon dioxide film to the high dielectric-constant gate insulating film. If the oxygen supplied to the high dielectric-constant gate insulating film spreads as far as a section above the channel of the transistor, the threshold of the transistor shifts. More specifically, if it is an n-channel transistor the threshold increases, and if it is a p-channel transistor the threshold decreases.

The amount by which the threshold of the transistor shifts in response to the oxygen supplied to the high dielectric-constant gate insulating film from the surroundings depends on the channel width W of the transistor, and also depends to a great extent on the surface area of the channel and the surface area of the high dielectric-constant gate insulating film on the silicon dioxide film of the STI.

Normally, the plurality of transistors which form a semiconductor device are formed in a mixture of various layouts. The amount of shift in the transistor may therefore differ depending on the layout. Further, in a CMOS (Complementary Metal-Oxide Semiconductor) circuit, n-channel transistors and p-channel transistors coexist. These factors give rise to the problem that it is difficult to control the threshold voltage in related semiconductor devices.

Supply of oxygen to the high dielectric-constant gate insulating film can be eliminated by using a nitride film as the insulating film which fills the STI. However, if the nitride film and the active region are too close to one another, another problem arises in that the reliability of the transistor falls, and this is therefore not practical.

### Means of Overcoming the Problems

A device according to one mode of embodiment of the present invention is a semiconductor device in which a gate structure, formed by successively laminating an insulating film having a high dielectric constant and an electrode film containing a metal material onto a substrate demarcated into an active region and an element isolation region surrounding the active region, extends across the element isolation region from the active region, characterized in that the element isolation region comprises a groove formed in the substrate, a first insulating film which covers sidewall surfaces of the groove and fills a lower portion of the groove, and a second insulating film which covers the first insulating film filling the lower portion of the groove, and which fills an upper portion of the groove.

A device according to another mode of embodiment of the present invention is characterized in that it comprises: a substrate demarcated into a memory cell region and a peripheral circuit region; a first element isolation region defined in the memory cell region and including a first groove; an active region defined in the peripheral circuit region; a second element isolation region defined in the peripheral circuit region and including a second groove surrounding the active region; a first insulating film including a first part filling the first groove, and a second part which covers sidewall surfaces of the second groove and fills a lower portion of the second groove; a second insulating film which covers the first insulating film filling the lower portion of the second groove, and which fills an upper portion of the second groove; and a gate structure which is formed by successively laminating onto the substrate an insulating film having a high dielectric constant and an electrode film containing a metal material, and which extends across the second element isolation region from the active region.

A method of manufacturing a device according to yet another mode of embodiment of the present invention is characterized in that it comprises: a step of forming a stopper film on a substrate; a step of patterning the stopper film and forming a groove in the substrate; a step of using FCVD to form a first insulating film which covers sidewall surfaces of the groove and fills a lower portion of the groove; a step of forming a second insulating film which covers the first insulating film and fills an upper portion of the groove; a step of carrying out polishing in such a way that the respective upper surfaces of the stopper film and the second insulating film form a substantially flat surface; a step of removing the stopper film; a step of forming a gate insulating film having a high dielectric constant; and a step of forming a gate electrode containing a metal material covering the gate insulating film.

### Advantages of the invention

According to the present invention, an oxygen supply path to the high dielectric-constant film of a transistor in which an HKMG construction is adopted is reduced, allowing a shift in the threshold voltage of the transistor to be suppressed. It is thus possible to control the threshold voltage of the transistor accurately, to eliminate layout-dependent variations in the threshold, and to obtain a highly reliable semiconductor device.

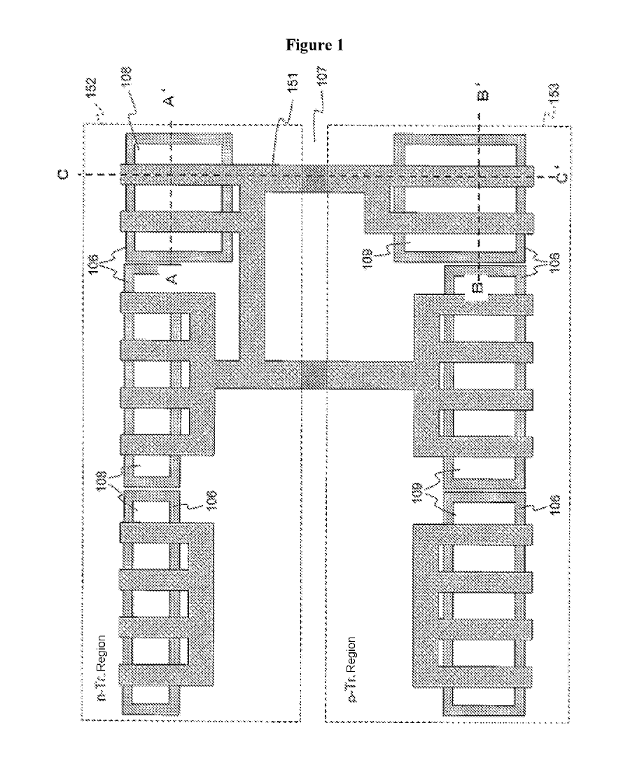

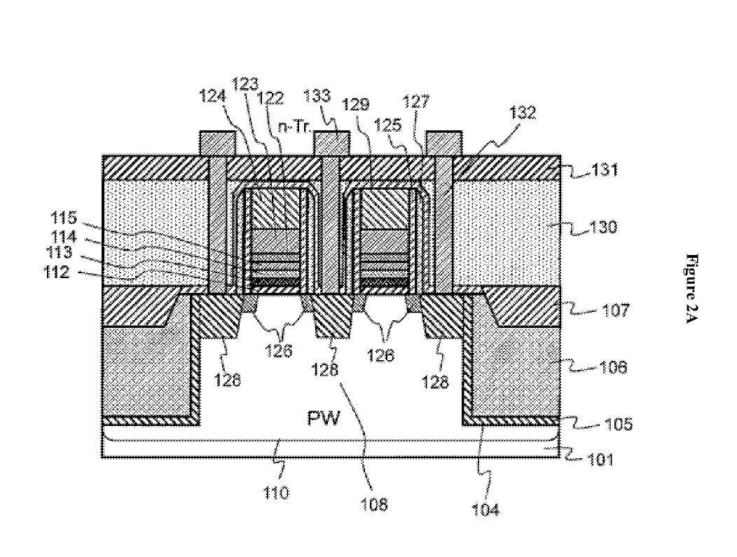

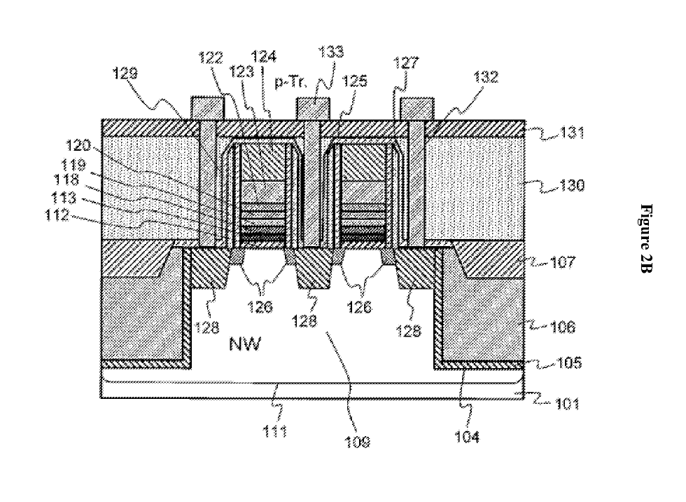

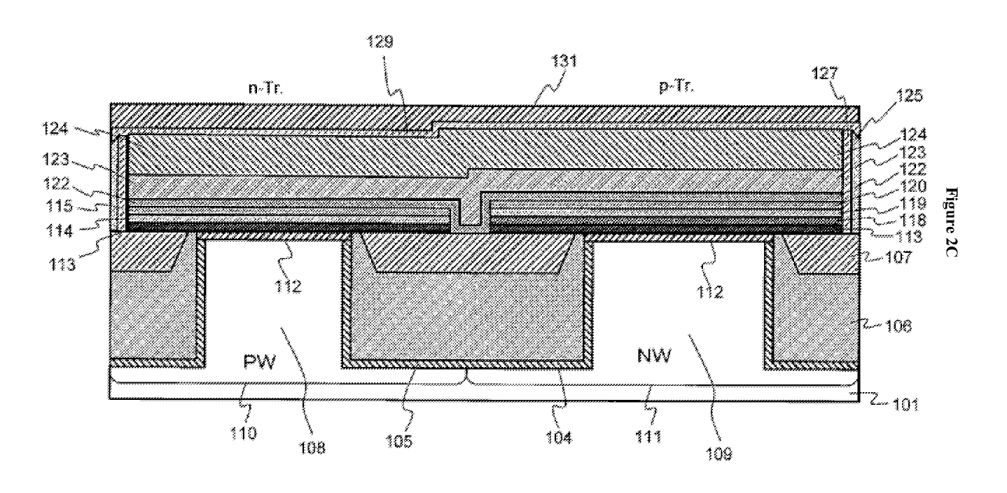

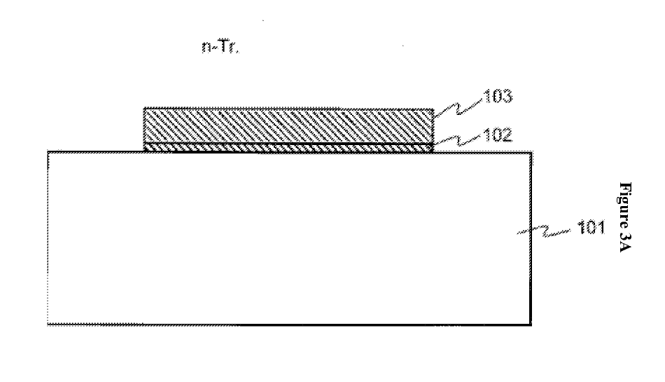

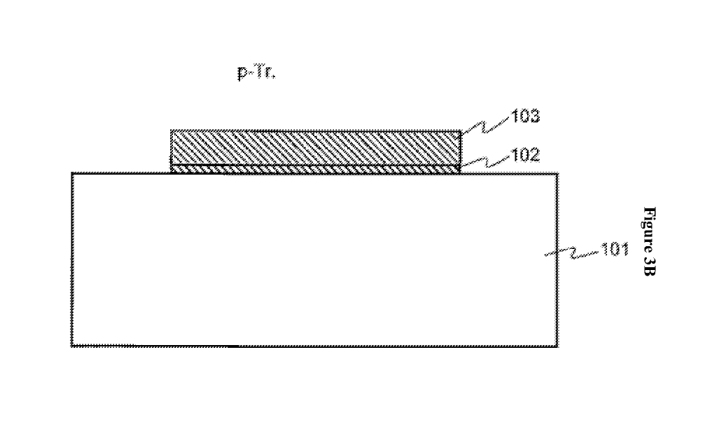

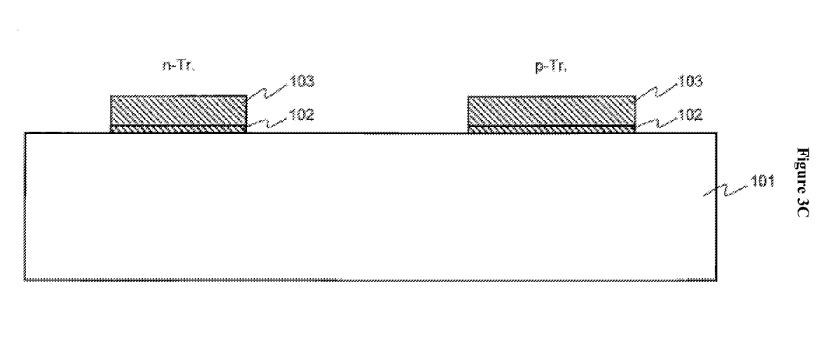

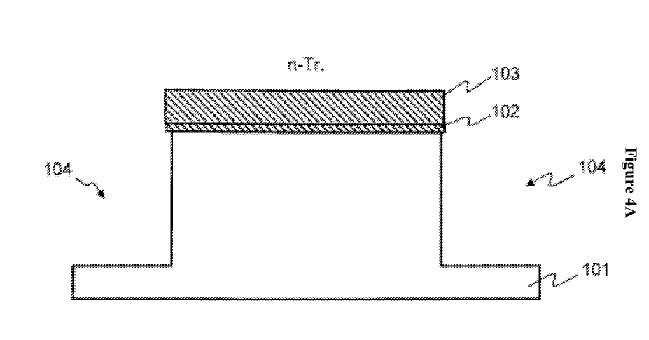

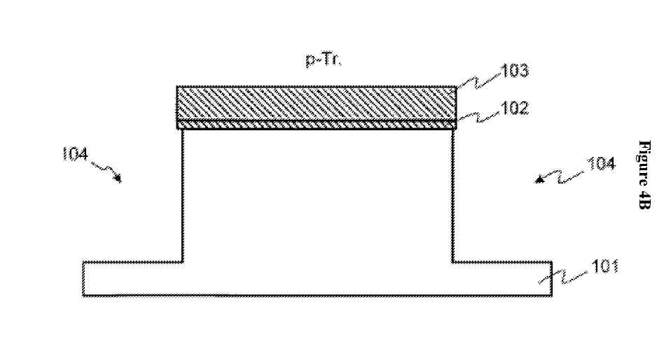

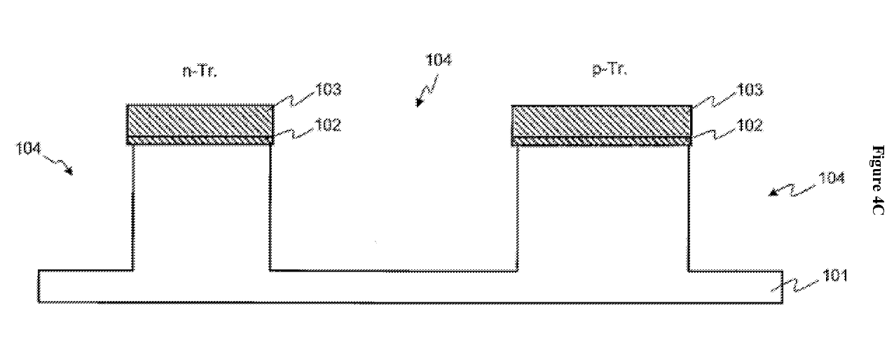

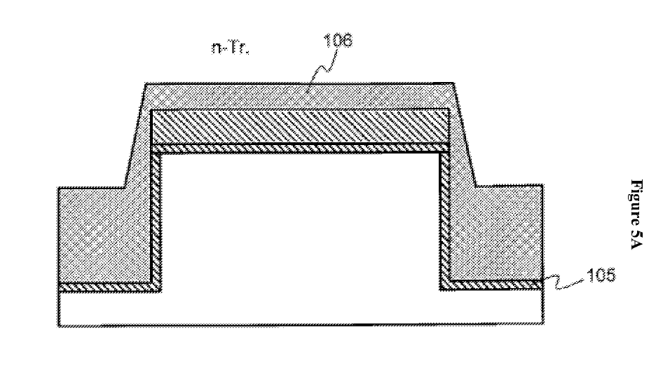

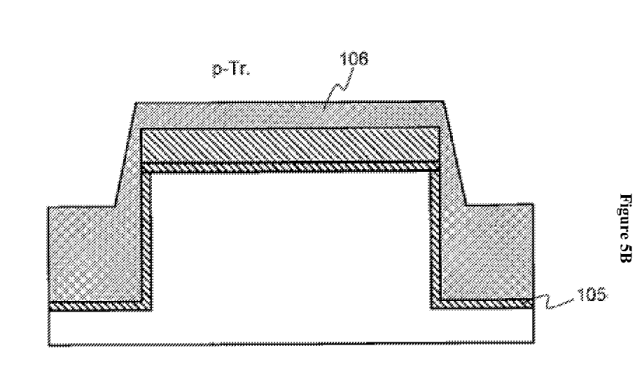

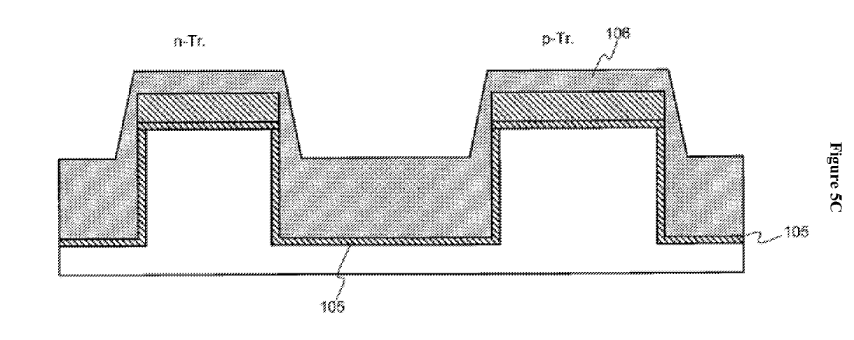

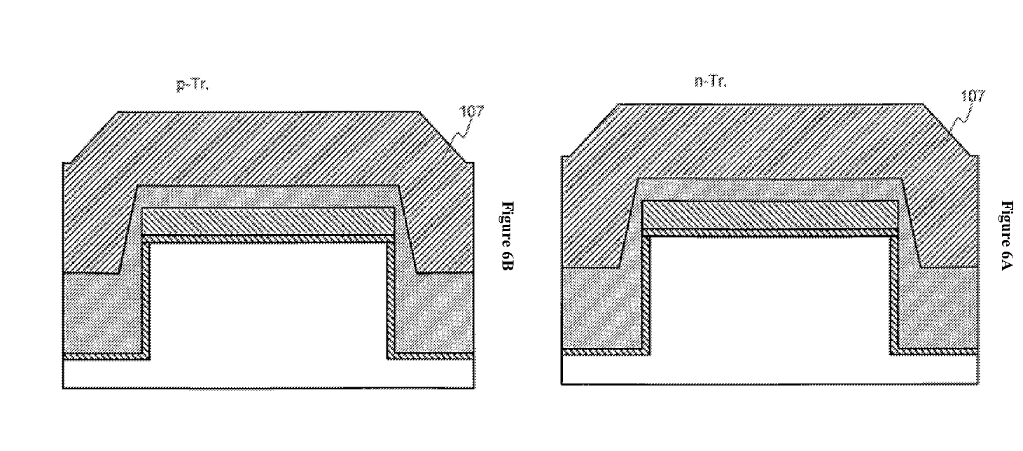

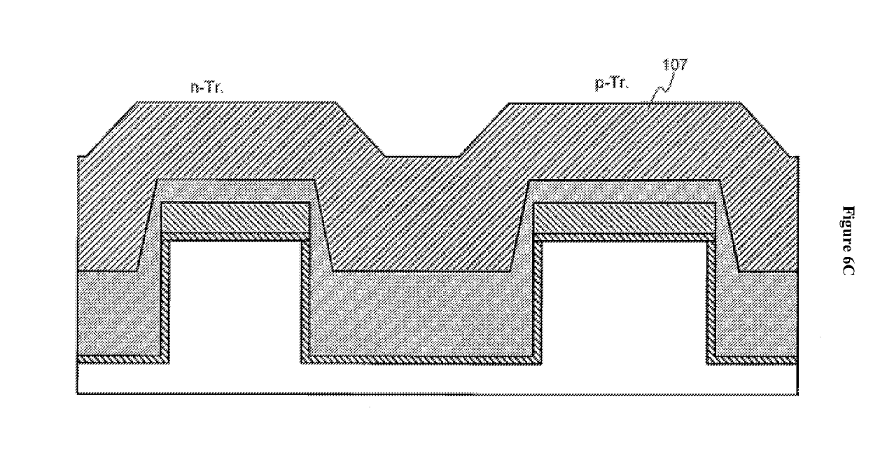

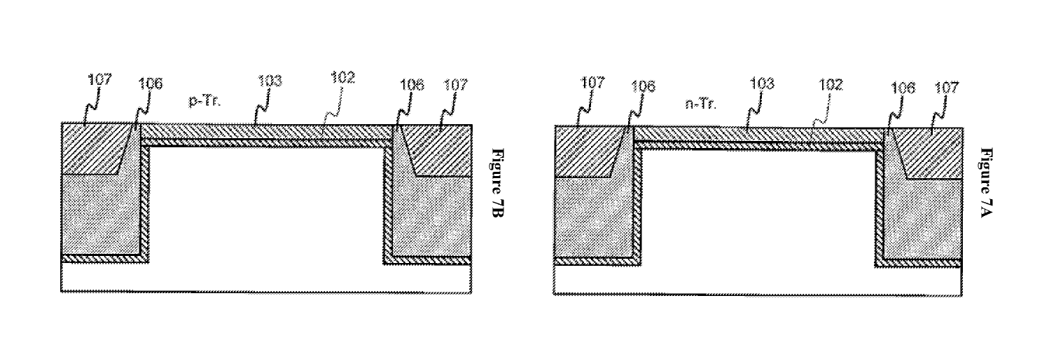

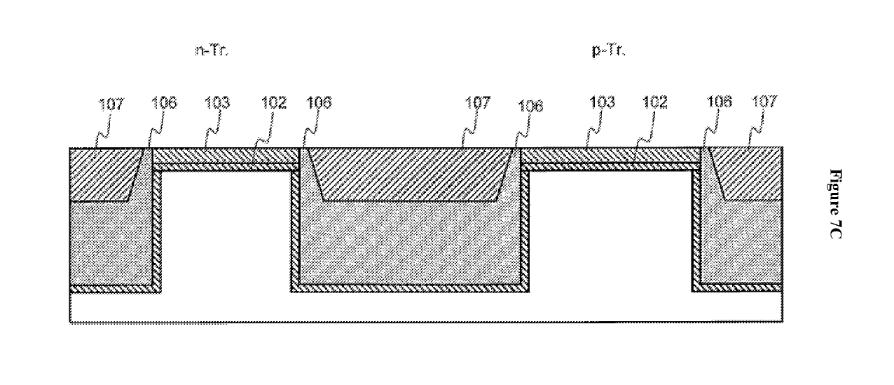

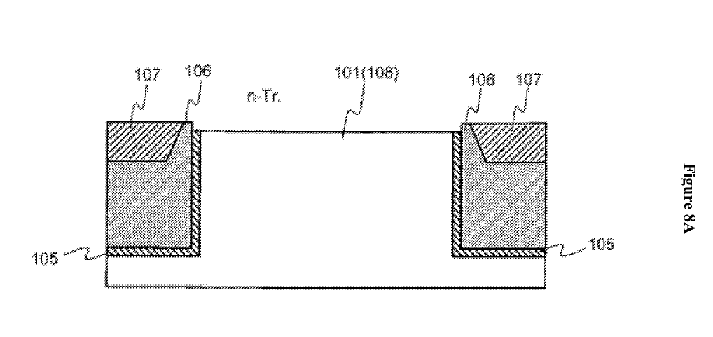

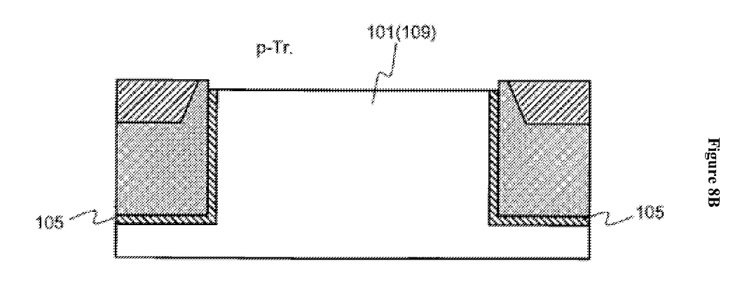

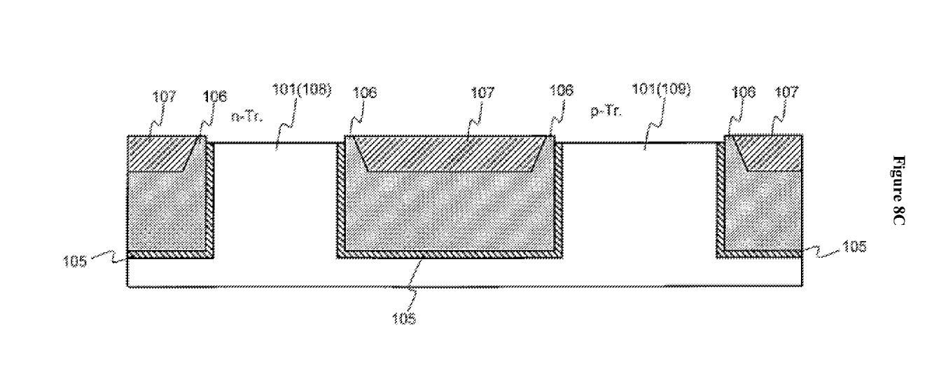

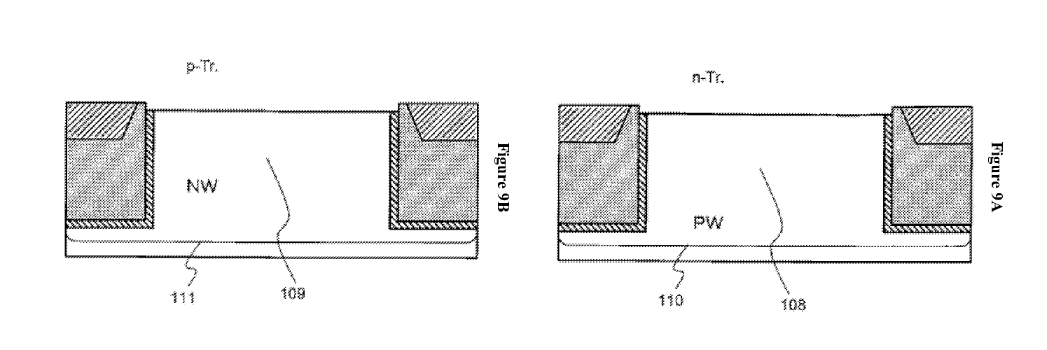

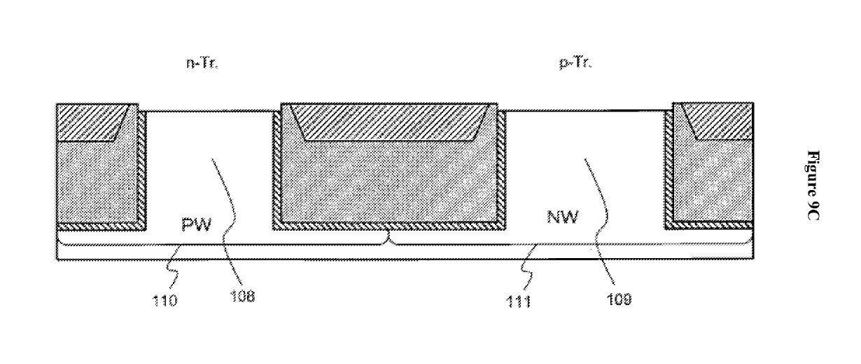

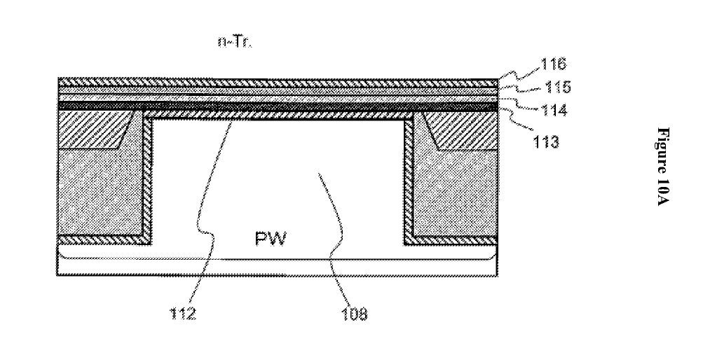

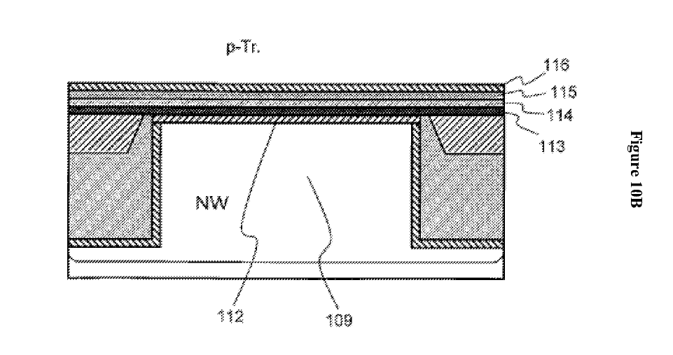

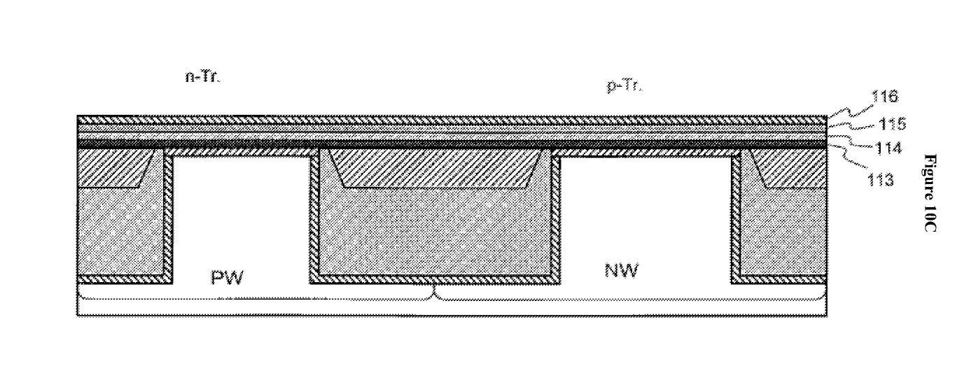

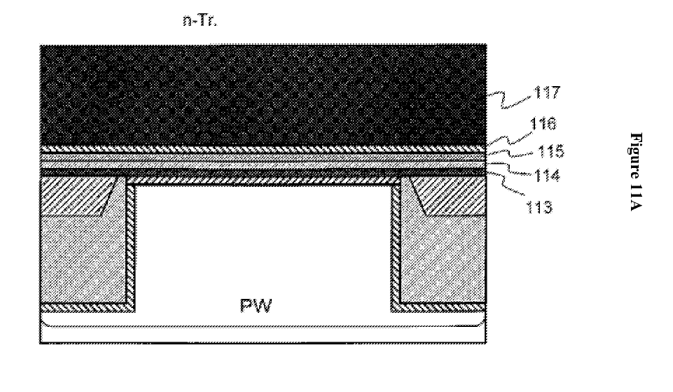

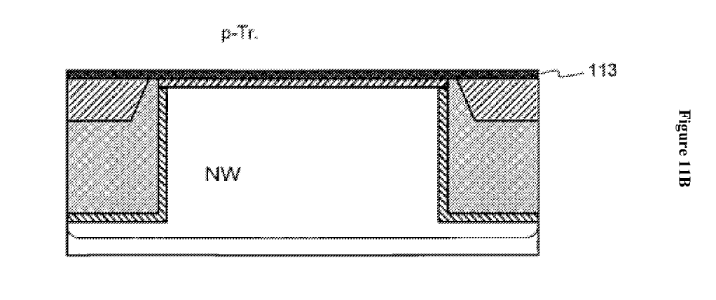

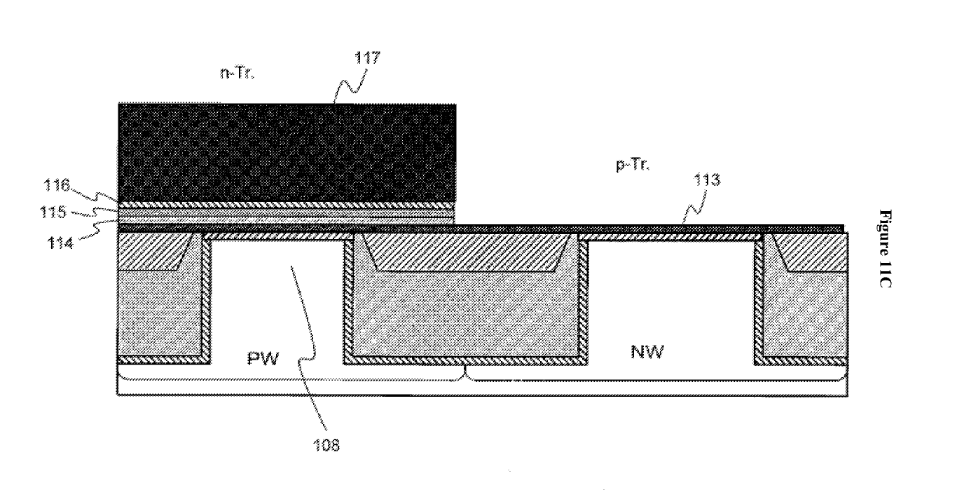

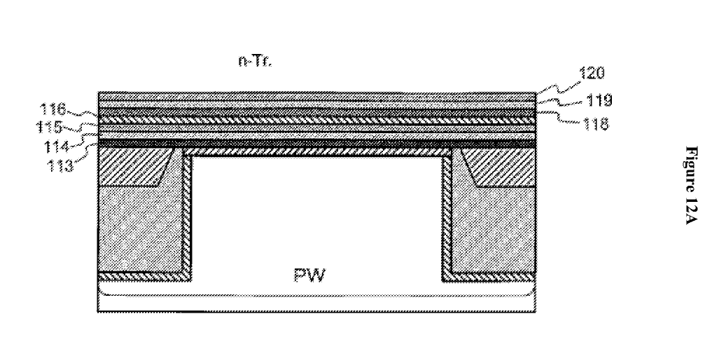

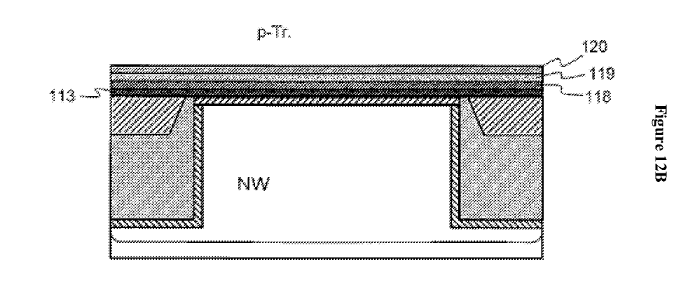

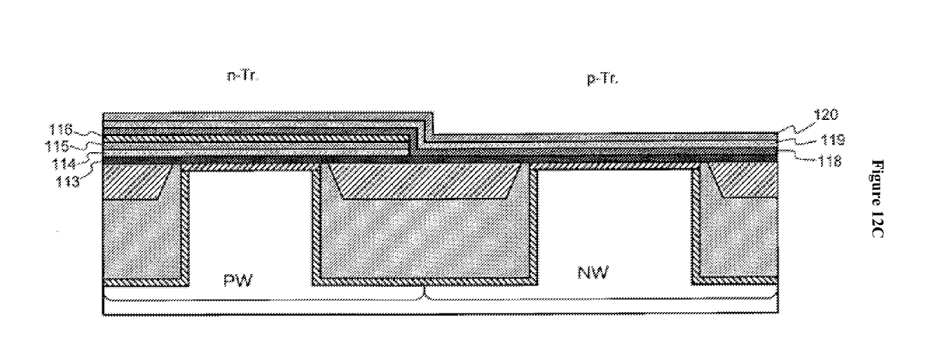

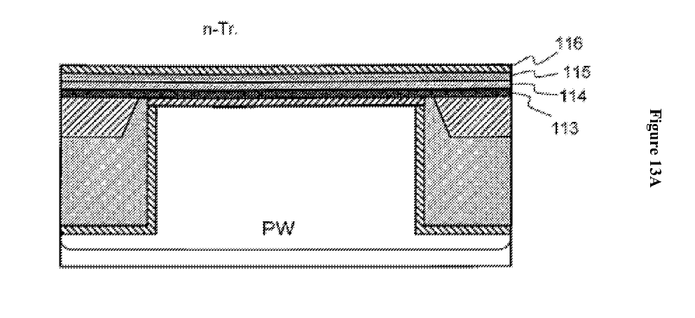

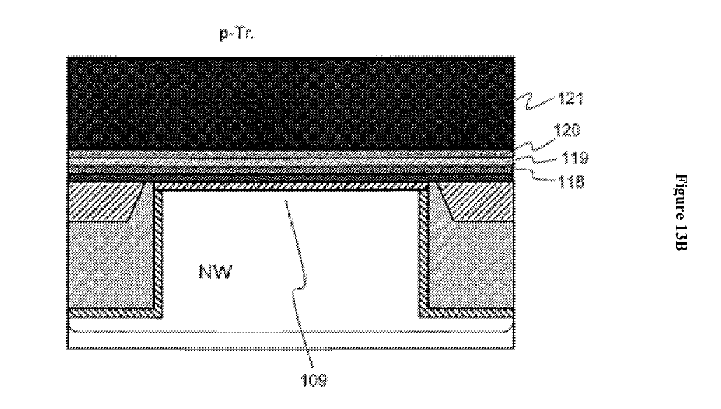

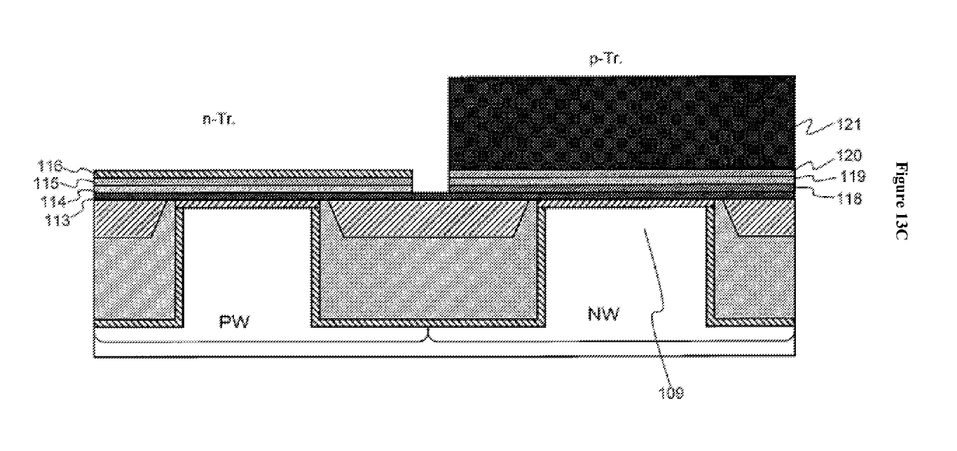

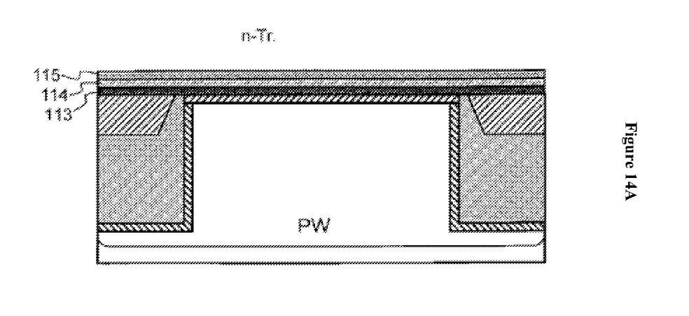

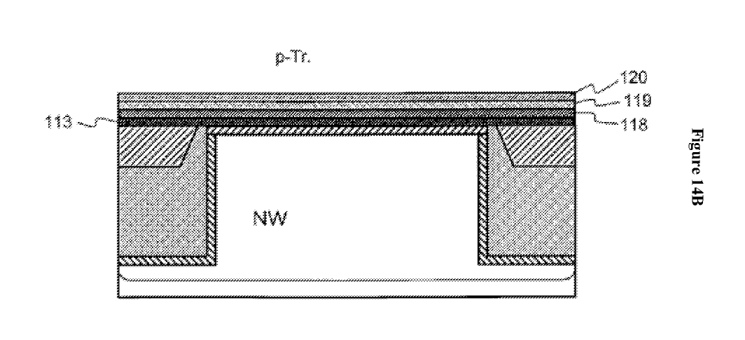

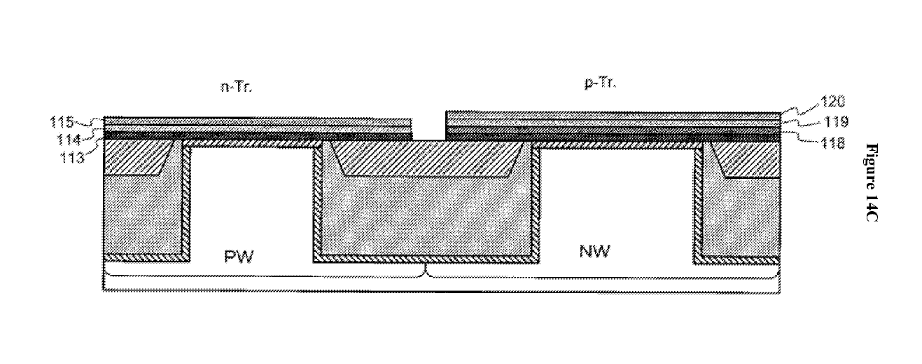

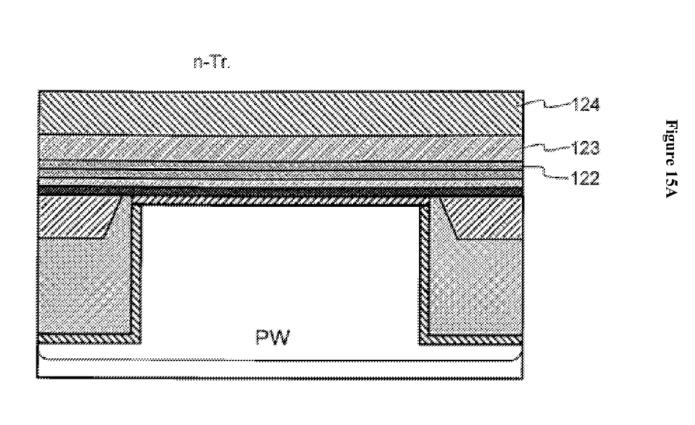

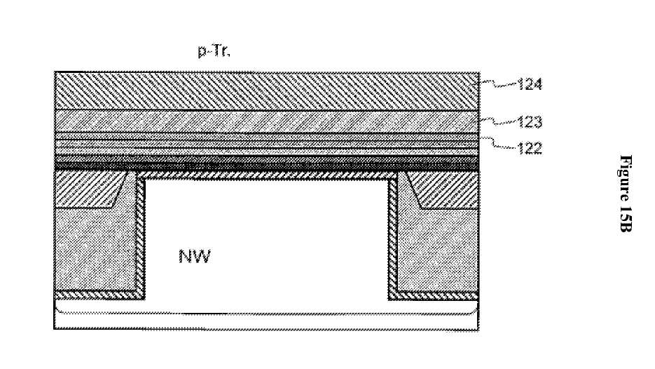

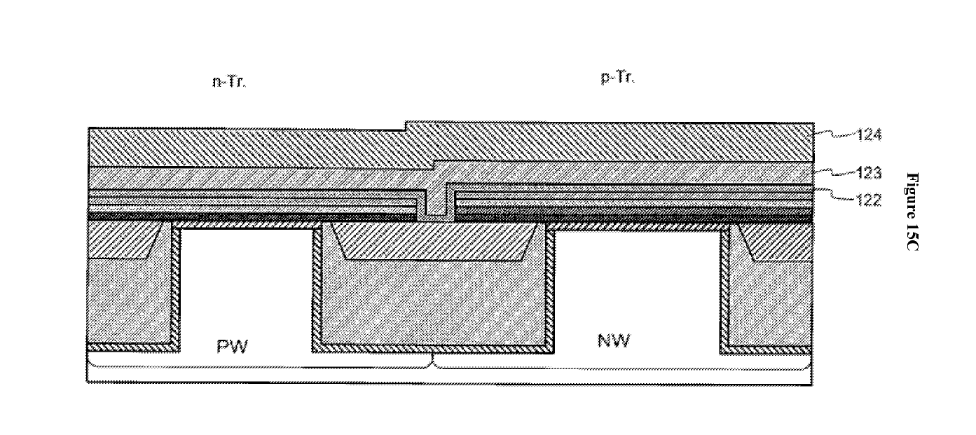

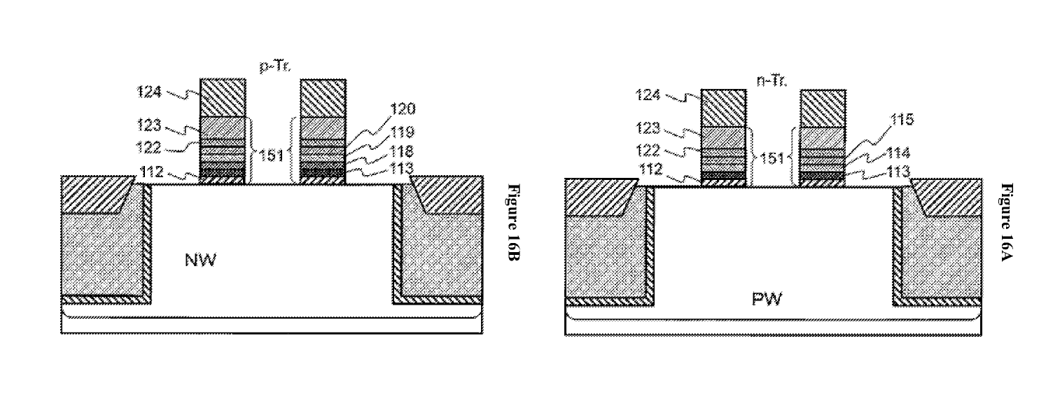

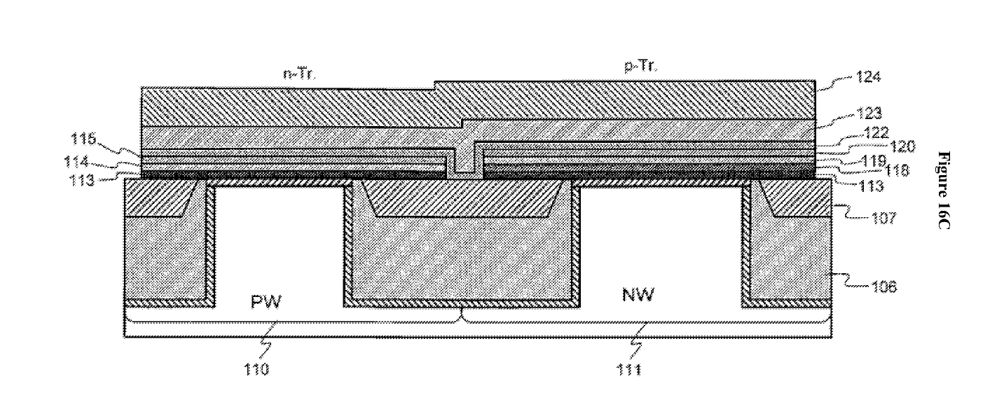

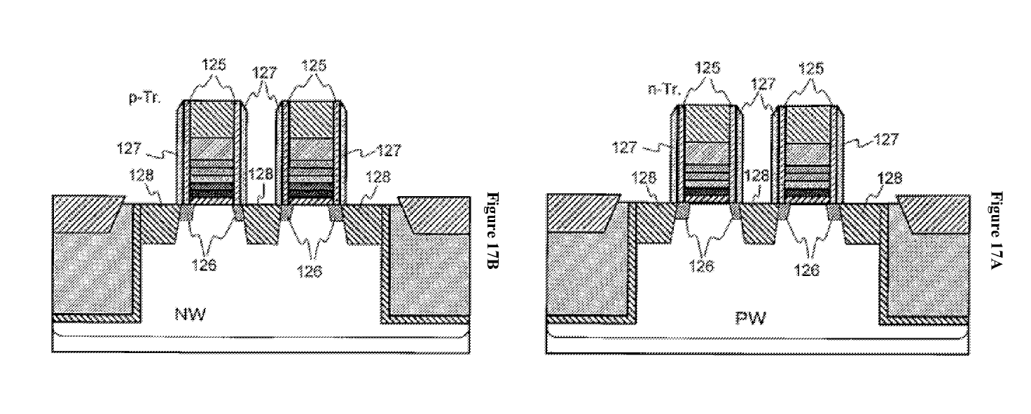

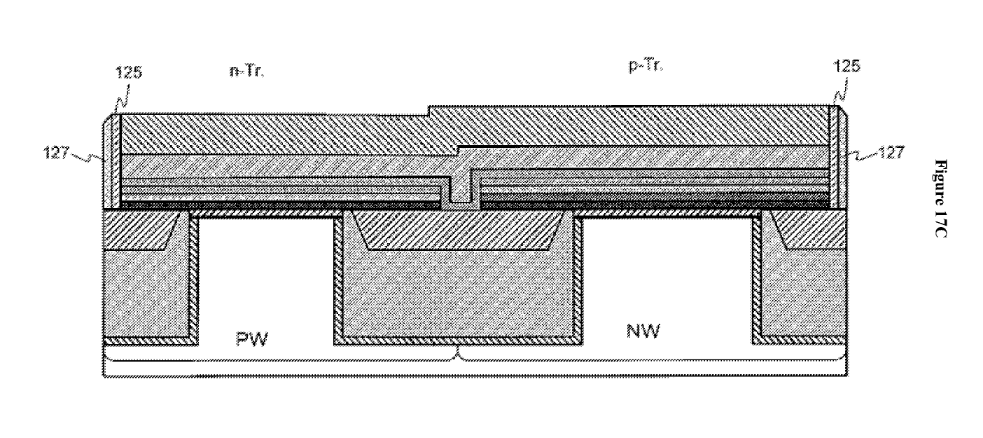

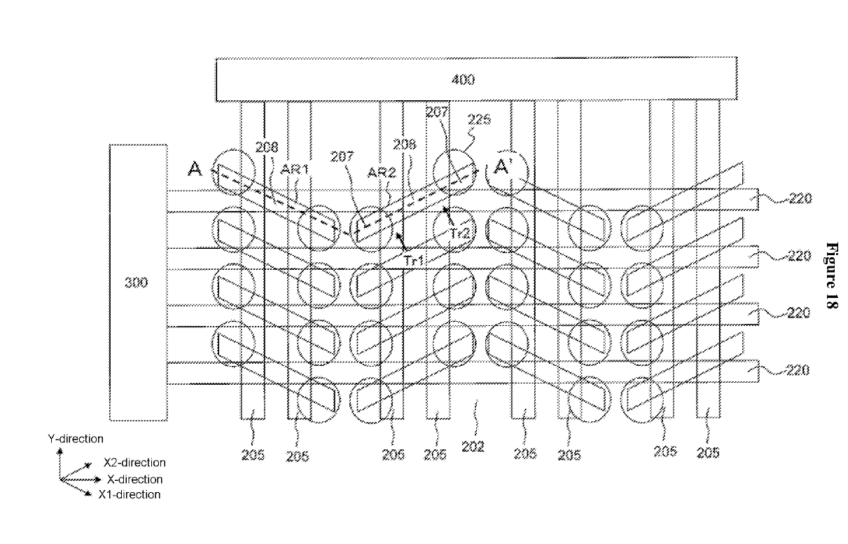

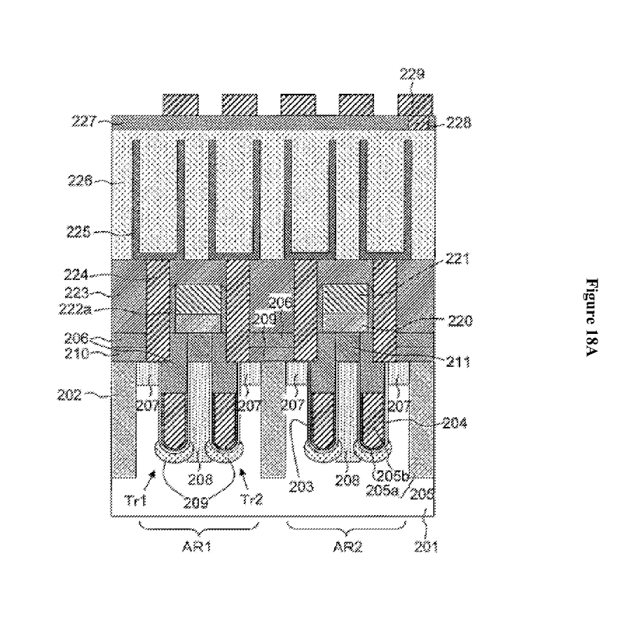

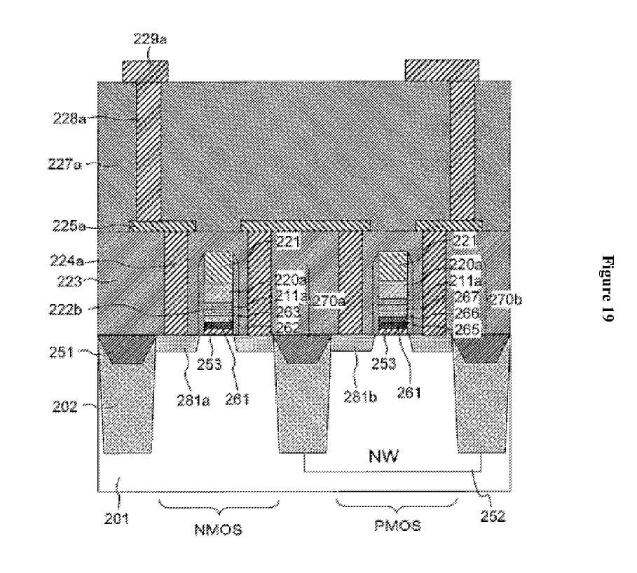

### BRIEF EXPLANATION OF THE DRAWINGS

[FIG. 1] is a drawing illustrating the planar layout of a semiconductor device according to a first mode of embodiment of the present invention.

[FIG. 2A] is a cross-sectional view along the line A-N in FIG. 1.

[FIG. 2B] is a cross-sectional view along the line B-W in FIG. 1.

[FIG. 2C] is a cross-sectional view along the line C-C in FIG. 1.

[FIG. 3A] is a drawing used to describe a method of manufacturing the semiconductor device according to the first mode of embodiment of the present invention, being a cross-sectional view in a position corresponding to the line A-N in FIG. 1.

[FIG. 3B] is a drawing used to describe the method of manufacturing the semiconductor device according to the first mode of embodiment of the present invention, being a cross-sectional view in a position corresponding to the line B-W in FIG. 1.

[FIG. 3C] is a drawing used to describe the method of manufacturing the semiconductor device according to the first mode of embodiment of the present invention, being a cross-sectional view in a position corresponding to the line C-C′ in FIG. 1.

[FIG. 4A] is a drawing used to describe the step following the step illustrated in FIGS. 3A, 3B and 3C, being a cross-sectional view in a position corresponding to the line A-N in FIG. 1.

[FIG. 4B] is a drawing used to describe the step following the step illustrated in FIGS. 3A, 3B and 3C, being a cross-sectional view in a position corresponding to the line B-W in FIG. 1.

[FIG. 4C] is a drawing used to describe the step following the step illustrated in FIGS. 3A, 3B and 3C, being a cross-sectional view in a position corresponding to the line C-C′ in FIG. 1. [FIG. 5A] is a drawing used to describe the step following the step illustrated in FIGS. 4A, 4B and 4C, being a cross-sectional view in a position corresponding to the line A-N in FIG. 1.

[FIG. 5B] is a drawing used to describe the step following the step illustrated in FIGS. 4A, 4B and 4C, being a cross-sectional view in a position corresponding to the line B-W in FIG. 1.

[FIG. 5C] is a drawing used to describe the step following the step illustrated in FIGS. 4A, 4B and 4C, being a cross-sectional view in a position corresponding to the line C-C′ in FIG. 1.

[FIG. 6A] is a drawing used to describe the step following the step illustrated in FIGS. 5A, 5B and 5C, being a cross-sectional view in a position corresponding to the line A-N in FIG. 1.

[FIG. 6B] is a drawing used to describe the step following the step illustrated in FIGS. 5A, 5B and 5C, being a cross-sectional view in a position corresponding to the line B-W in FIG. 1. [FIG. 6C] is a drawing used to describe the step following the step illustrated in FIGS. 5A, 5B and 5C, being a cross-sectional view in a position corresponding to the line C-C′ in FIG. 1.

[FIG. 7A] is a drawing used to describe the step following the step illustrated in FIGS. 6A, 6B and 6C, being a cross-sectional view in a position corresponding to the line A-N in FIG. 1.

[FIG. 7B] is a drawing used to describe the step following the step illustrated in FIGS. 6A, 6B and 6C, being a cross-sectional view in a position corresponding to the line B-W in FIG. 1.

[FIG. 7C] is a drawing used to describe the step following the step illustrated in FIGS. 6A, 6B and 6C, being a cross-sectional view in a position corresponding to the line C-C′ in FIG. 1.

[FIG. 8A] is a drawing used to describe the step following the step illustrated in FIGS. 7A, 7B and 7C, being a cross-sectional view in a position corresponding to the line A-N in FIG. 1. [FIG. 8B] is a drawing used to describe the step following the step illustrated in FIGS. 7A, 7B and 7C, being a cross-sectional view in a position corresponding to the line B-W in FIG. 1.

[FIG. 8C] is a drawing used to describe the step following the step illustrated in FIGS. 7A, 7B and 7C, being a cross-sectional view in a position corresponding to the line C-C′ in FIG. 1.

[FIG. 9A] is a drawing used to describe the step following the step illustrated in FIGS. 8A, 8B and 8C, being a cross-sectional view in a position corresponding to the line A-N in FIG. 1.

[FIG. 9B] is a drawing used to describe the step following the step illustrated in FIGS. 8A, 8B and 8C, being a cross-sectional view in a position corresponding to the line B-W in FIG. 1.

[FIG. 9C] is a drawing used to describe the step following the step illustrated in FIGS. 8A, 8B and 8C, being a cross-sectional view in a position corresponding to the line C-C′ in FIG. 1.

[FIG. 10A] is a drawing used to describe the step following the step illustrated in FIGS. 9A, 9B and 9C, being a cross-sectional view in a position corresponding to the line A-N in FIG. 1.

[FIG. 10B] is a drawing used to describe the step following the step illustrated in FIGS. 9A, 9B and 9C, being a cross-sectional view in a position corresponding to the line B-W in FIG. 1.

[FIG. 10C] is a drawing used to describe the step following the step illustrated in FIGS. 9A, 9B and 9C, being a cross-sectional view in a position corresponding to the line C-C′ in FIG. 1.

[FIG. 11A] is a drawing used to describe the step following the step illustrated in FIGS. 10A, 10B and 10C, being a cross-sectional view in a position corresponding to the line A-N in FIG. 1.

[FIG. 11B] is a drawing used to describe the step following the step illustrated in FIGS. 10A, 10B and 10C, being a cross-sectional view in a position corresponding to the line B-W in FIG. 1.

[FIG. 11C] is a drawing used to describe the step following the step illustrated in FIGS. 10A, 10B and 10C, being a cross-sectional view in a position corresponding to the line C-C′ in FIG. 1.

[FIG. 12A] is a drawing used to describe the step following the step illustrated in FIGS. 11A, 11B and 11C, being a cross-sectional view in a position corresponding to the line A-N in FIG. 1.

[FIG. 12B] is a drawing used to describe the step following the step illustrated in FIGS. 11A, 11B and 11C, being a cross-sectional view in a position corresponding to the line B-B′ in FIG. 1.

[FIG. 12C] is a drawing used to describe the step following the step illustrated in FIGS. 11A, 11B and 11C, being a cross-sectional view in a position corresponding to the line C-C′ in FIG. 1.

[FIG. 13A] is a drawing used to describe the step following the step illustrated in FIGS. 12A, 12B and 12C, being a cross-sectional view in a position corresponding to the line A-N in FIG. 1.

[FIG. 13B] is a drawing used to describe the step following the step illustrated in FIGS. 12A, 12B and 12C, being a cross-sectional view in a position corresponding to the line B-B′ in FIG. 1.

[FIG. 13C] is a drawing used to describe the step following the step illustrated in FIGS. 12A, 12B and 12C, being a cross-sectional view in a position corresponding to the line C-C′ in FIG. 1.

[FIG. 14A] is a drawing used to describe the step following the step illustrated in FIGS. 13A, 13B and 13C, being a cross-sectional view in a position corresponding to the line A-N in FIG. 1.

[FIG. 14B] is a drawing used to describe the step following the step illustrated in FIGS. 13A, 13B and 13C, being a cross-sectional view in a position corresponding to the line B-B′ in FIG. 1.

[FIG. 14C] is a drawing used to describe the step following the step illustrated in FIGS. 13A, 13B and 13C, being a cross-sectional view in a position corresponding to the line C-C′ in FIG. 1.

[FIG. 15A] is a drawing used to describe the step following the step illustrated in FIGS. 14A, 14B and 14C, being a cross-sectional view in a position corresponding to the line A-N in FIG. 1.

[FIG. 15B] is a drawing used to describe the step following the step illustrated in FIGS. 14A, 14B and 14C, being a cross-sectional view in a position corresponding to the line B-W in FIG. 1.

[FIG. 15C] is a drawing used to describe the step following the step illustrated in FIGS. 14A, 14B and 14C, being a cross-sectional view in a position corresponding to the line C-C′ in FIG. 1.

[FIG. 16A] is a drawing used to describe the step following the step illustrated in FIGS. 15A, 15B and 15C, being a cross-sectional view in a position corresponding to the line A-N in FIG. 1.

[FIG. 16B] is a drawing used to describe the step following the step illustrated in FIGS. 15A, 15B and 15C, being a cross-sectional view in a position corresponding to the line B-W in FIG. 1.

[FIG. 16C] is a drawing used to describe the step following the step illustrated in FIGS. 15A, 15B and 15C, being a cross-sectional view in a position corresponding to the line C-C′ in FIG. 1.

[FIG. 17A] is a drawing used to describe the step following the step illustrated in FIGS. 16A, 16B and 16C, being a cross-sectional view in a position corresponding to the line A-N in FIG. 1.

[FIG. 17B] is a drawing used to describe the step following the step illustrated in FIGS. 16A, 16B and 16C, being a cross-sectional view in a position corresponding to the line B-W in FIG. 1.

[FIG. 17C] is a drawing used to describe the step following the step illustrated in FIGS. 16A, 16B and 16C, being a cross-sectional view in a position corresponding to the line C-C′ in FIG. 1.

[FIG. 18] is a drawing illustrating the planar layout of a semiconductor device according to a second mode of embodiment of the present invention.

[FIG. 18A] is a cross-sectional view along the line A-N in FIG. 18.

[FIG. 19] is a cross-sectional view illustrating part of the peripheral circuit portion of the semiconductor device according to the second mode of embodiment of the present invention.

### MODES OF EMBODYING THE INVENTION

Modes of embodying the present invention will now be described in detail with reference to the drawings.

FIG. 1 is a drawing illustrating the planar layout of part of a semiconductor device according to a first mode of embodiment of the present invention. Here, a DRAM (Dynamic Random Access Memory) is taken to be the semiconductor device, and FIG. 1 illustrates part of a peripheral circuit thereof (a CMOS circuit). However, the present invention is not limited to DRAMs, and can also be applied to various other semiconductor devices.

The upper side of FIG. 1 is an n-channel transistor (n-Tr) region, and the lower side is a p-channel transistor (p-Tr) region. A plurality of active regions 108 and 109 are defined in each of the transistor regions. Further, the periphery of each active region 108 and 109 is surrounded by an STI (Shallow Trench Isolation) element isolation region.

The STI element isolation regions are formed by filling an STI groove (104 in FIGS. 4A, 4B and 4C) by a flowable oxide film 106 and a silicon nitride film 107. In FIG. 1 it appears as though the flowable oxide film 106 surrounds the periphery of the active regions 108 and 109, and that the silicon nitride film 107 is disposed further to the periphery thereof However, the flowable oxide film 106 also exists underneath (to the rear in the drawing) the silicon nitride film 107. In other words, the flowable oxide film 106 is formed in such a way as to cover the sidewall surfaces of the STI grooves and to fill a lower portion of the groves, and the silicon nitride film 107 is formed thereon in such a way as to fill an upper portion of the grooves.

A transistor is formed in each of the active regions 108 and 109. The layout of the transistors in each region differs depending on the conduction type and the application, for example.

Further, a gate structure 151 is formed extending across the STI element isolation regions from the active regions 108 and 109. As illustrated by the two types of hatching, the gate structure 151 includes two types of structural parts. The boundary between these structural parts coincides with the boundary between a first gate stack PR resist mask region 152 and a second gate stack PR resist mask region 153. Here, we will focus on one of two types of structural parts of the gate structure 151 (the part formed on the active regions). For the gate structure 151, a construction (HKMG construction) is adopted in which, in the active region and the parts connected thereto, an insulating film (high dielectric-constant gate insulating film, HK film) having a high dielectric constant, and a metal film (metal gate electrode film) containing a metal material are laminated together. However, strictly speaking, there is a slight difference between the configurations of the part formed in the n-channel transistor region and the part formed in the p-channel transistor region of the gate structure 151, but this difference is not directly relevant to the present invention.

As can be understood from FIG. 1, in this mode of embodiment the surface area of the region in which the gate structure 151 and the flowable oxide film 106 overlap is noticeably smaller than the surface area of the region in which the gate structure 151 overlaps the STI element isolation regions. This means that the route by which oxygen is supplied from the STI element isolation region to the high dielectric-constant film (113 in FIGS. 2A, 2B and 2C) contained in the gate structure 151 is narrow. According to this construction, oxygen does not readily spread as far as the channel region of the transistor by way of the metal gate electrode film and the high dielectric-constant film contained in the gate structure 151. Consequently the problem of variation in the threshold of the transistor, resulting in variability in the electrical properties of the circuit, also does not readily occur. Further, the silicon nitride film 107 which fills the STI element isolation region does not fill the STI groove completely, but only to between ⅕ and ½ of its depth, and therefore no junction leakage or deterioration in the reliability of the transistor arise as a result of stress generated in the silicon nitride film 107.

The construction of the semiconductor device in FIG. 1 will now be described in detail with reference to FIGS. 2A, 2B and 2C.

FIGS. 2A, 2B and 2C are respectively a cross-sectional view along the line A-N, a cross-sectional view along the line B-W and a cross-sectional view along the line C-C′ in FIG. 1. However, these drawings illustrate the state midway through the manufacture of the semiconductor device. Further, in the drawings, the size and the horizontal to vertical ratio of each part differ from those in an actual semiconductor device.

Referring to FIGS. 2A, 2B and 2C, a p-type well (PW) 110 is formed in an n-channel transistor forming region on one surface side of a semiconductor substrate 101, and an n-type well (NW) 111 is formed in a p-channel transistor forming region.

Further, STI grooves 104 are formed in the semiconductor substrate 101. A pad silicon dioxide film 105 is formed on the inner surfaces of the grooves 104. Then lower portions of the grooves 104 are filled by a flowable oxide film 106 (a first insulating film) formed in such a way as to cover the sidewall surfaces of the grooves 104. Further, upper portions of the grooves 104 are filled by a silicon nitride film 107 (a second insulating film).

The STI element isolation regions are formed from the flowable oxide film 106 and the silicon nitride film 107. The active regions 108 and 109 are then defined by being surrounded by the STI element isolation regions.

LDD (Lightly Doped Drain) regions 126 and S/D (Source/Drain) regions 128 are formed in the active regions 108 and 109 by ion implantation.

Referring to FIGS. 2A and 2C, a lower-layer gate insulating film 112, a first high dielectric-constant film 113, a first metal gate electrode film 114, a first (non-doped) amorphous (a-Si) silicon gate electrode film 115, a third (phosphorus-doped) amorphous silicon gate electrode film 122, a metal laminated film 123 and a hard mask silicon nitride film 124 are formed in a laminated manner on the active region 108. This laminated construction forms the gate structures 151 in the n-channel transistor region.

Further, referring to FIGS. 2B and 2C, the lower-layer gate insulating film 112, the first high dielectric-constant film 113, a second high dielectric-constant film 118, a second metal gate electrode film 119, a second amorphous silicon gate electrode film 120, the third amorphous silicon gate electrode film 122, the metal laminated film 123 and the hard mask silicon nitride film 124 are formed in a laminated manner on the active region 109. This laminated construction forms the gate structures 151 in the p-channel transistor region.

Although the details of the gate structures 151 in the n-channel transistor region and the gate structures 151 in the p-channel transistor region differ, they have a commonality in that they are provided with the lower-layer gate insulating film (112), the gate insulating film having a high dielectric constant (113, 118), and the gate electrode film (114, 119) (in that an HKMG construction is adopted).

As can be seen in FIG. 2C, the gate structures 151 also exist above the STI element isolation regions, except in the boundary part between the p-well region and the n-well region. In the STI element isolation regions, it is mostly the silicon nitride film 107 that is in contact with the gate structure 151.

Referring again to FIGS. 2A, 2B and 2C, offset spacers 125 and side wall spacers 127 are formed on the side surfaces of the gate structures 151.

A liner silicon nitride film 129 is formed in such a way as to cover the gate structures 151 on the side surfaces of which the spacers 125 and 127 have been formed. Further, an interlayer insulating film 130 is formed in such a way as to embed the gate structures 151 covered by the liner silicon nitride film 129. Further, a cap silicon dioxide film 131 is formed on the interlayer insulating film 130.

Connecting plugs 132 connected to the S/D regions 128 are formed penetrating through the cap silicon dioxide film 131 and the inter wiring-layer insulating film 130, and wiring lines 133 connected to the connecting plugs 132 are formed on the cap silicon dioxide film 131.

In the semiconductor device configured as discussed hereinabove, the thickness of the flowable oxide film 106 is set in such a way that no adverse effects arise as a result of employing the silicon nitride films 107 in the STI element isolation regions. More specifically, the thickness of the flowable oxide film 106 is between ½ and ⅘ of the depth of the groove 104, measured from the bottom surface of the groove 104. Further, in a location corresponding to the surface of the active regions 108 and 109, said film thickness measured from the sidewall surface of the groove is between 10 and 100 nm.

According to the abovementioned configuration, in this mode of embodiment the surface area of the first high dielectric-constant film 113 in contact with the flowable oxide film 106 is small. As a result it is possible substantially to eliminate the spread of oxygen from the flowable oxide film 106 to the first high dielectric-constant film 113 when an annealing process is performed. Further, no junction leakage or deterioration in the reliability of the transistor arise as a result of stress generated in the silicon nitride film 107.

A method of manufacturing the semiconductor device according to this mode of embodiment will next be described with reference to FIG. 3A to FIG. 17C. Here, drawings having a drawing number with the letter A appended are cross-sectional views in a location corresponding to the line A-N in FIG. 1, drawings with the letter B appended are cross-sectional views in a location corresponding to the line B-W in FIG. 1, and drawings with the letter C appended are cross-sectional views in a location corresponding to the line C-C in FIG. 1.

First, as illustrated in FIGS. 3A, 3B and 3C, a pad silicon dioxide film (thermally-oxidized film) 102 and a hard mask silicon nitride film 103 are formed successively on one surface of a semiconductor substrate (silicon substrate) 101, and the pad silicon dioxide film 102 and the hard mask silicon nitride film 103 on the regions which are to form the element isolation regions are removed by etching.

Next, as illustrated in FIGS. 4A, 4B and 4C, the semiconductor substrate 101 is etched, using the hard mask silicon nitride film 103 as a mask, to form the STI grooves 104.

Next, as illustrated in FIGS. 5A, 5B and 5C, the pad silicon dioxide film (thermally-oxidized film) 105 is formed on the inner wall surfaces and the bottom surfaces of the grooves 104 by thermal oxidation. The flowable oxide film 106 is then formed as the first insulating film by FCVD in such a way as to cover the entire surface.

The flowable oxide film 106 can for example be obtained by forming a film containing silicon and nitrogen on the semiconductor substrate by simultaneously supplying a precursor containing silicon and a precursor containing radical nitrogen into a film-forming chamber, and then heat-treating, under an ozone atmosphere, the film containing silicon and nitrogen that has been formed, to change said film into a film containing silicon and oxygen. The film containing silicon and nitrogen is flowable, but the film containing silicon and oxygen, obtained by heat-treatment (reflow treatment) under an ozone atmosphere, loses its flowability.

The flowable oxide film 106 is formed in such a way as to cover the sidewall surfaces of the grooves 104 and to fill the lower portions of the grooves 104 to between ½ and ⅘ of the groove depth. On account of the flowability during film deposition, the thickness (in the left-right direction in the drawing) of the flowable oxide film 106 formed on the sidewall surfaces of the grooves 104 gradually increases from the upper portion of the groove 104 toward the bottom portion thereof. The flowable oxide film 106 is formed in such a way that the thickness of the flowable oxide film 106 formed on the sidewall surfaces of the grooves 104 is between 10 nm and 100 nm in a location corresponding to the upper surface of the semiconductor substrate 101. The thickness of the flowable oxide film can be adjusted by varying the deposition conditions and the reflow conditions in accordance with the depth and the aspect ratio of the grooves 104.

Next, as illustrated in FIGS. 6A, 6B and 6C, the silicon nitride film 107 is formed as the second insulating film to a thickness such that it completely fills the upper portions of the grooves 104, in such a way as to cover the flowable oxide film 106. The second insulating film should be an insulating film that does not contain oxygen.

The silicon nitride film 107 is then etched back until the flowable oxide film 106 is exposed. The upper surfaces of the exposed flowable oxide film 106 and the silicon nitride film 107 are then polished using CMP to planarize the upper surfaces. This polishing is performed using the hard mask silicon nitride film 103 as a stopper film. Alternatively, the polishing may be continued further until part of the hard mask silicon nitride film 103 has been removed, as illustrated in FIGS. 7A, 7B and 7C.

Next, as illustrated in FIGS. 8A, 8B and 8C, the hard mask silicon nitride film 103 and the pad silicon dioxide film 102 are removed using wet etching, to expose the semiconductor substrate 101.

The STI element isolation regions having a two-layer construction, in which the grooves 104 formed in the semiconductor substrate 101 are filled by the flowable oxide film 106 and the silicon nitride film 107, are completed as discussed hereinabove. The STI element isolation regions (106 and 107), and the active regions 108 and 109 surrounded by the STI element isolation regions, are thereby formed in a demarcated manner on one surface side of the semiconductor substrate 101.

Next, the pad silicon dioxide film (which is not shown in the drawings) is again formed on the exposed surface of the semiconductor substrate 101. The p-type wells 110 and the n-type wells 111 are then formed by ion implantation, as illustrated in FIGS. 9A, 9B and 9C, then a channel stopper is formed in the wells, and channel doping is performed. The pad oxide film is then removed.

Next, as illustrated in FIGS. 10A, 10B and 10C, the lower-layer gate insulating films (silicon dioxide films) 112 are formed on the upper surfaces of the active regions 108 and 109 by thermal oxidation. The first high dielectric-constant film 113, the first metal gate electrode film 114, the first amorphous silicon gate electrode film 115 and a protective silicon dioxide film 116 are then successively laminated.

The first high dielectric-constant film 113 is an insulating film having a dielectric constant that is higher than that of the silicon dioxide (SiO₂) film, and an HfO₂ film or an HfSiO film can, for example, be used. These films can be formed by ALD (Atomic Layer Deposition).

The first metal gate electrode film 114 comprises a material containing a metal, and a TiN film or a TaN film can, for example, be used. These films can be formed by ALD or PVD (Physical Vapor Deposition).

The first amorphous silicon gate electrode film 115 is a non-doped amorphous silicon gate film, and can be formed by LPCVD (Low Pressure Chemical Vapor Deposition), for example.

The protective silicon dioxide film 116 can be formed by plasma CVD, for example.

Next, as illustrated in FIGS. 11A, 11B and 11C, a first gate stack lithographic resist mask 117 is formed in such a way as to cover the p-well regions. The protective silicon dioxide film 116 that is not covered by the first gate stack lithographic resist mask 117 is then removed by dry etching, using the first gate stack lithographic resist mask 117 as a mask. The exposed first amorphous silicon gate electrode film 115 and the first metal gate electrode film 114 are then removed successively by wet etching, using the first gate stack lithographic resist mask 117 and the remaining protective silicon dioxide film 116 as a mask. By this means, a first gate stack, in which the first high dielectric-constant film 113, the first metal gate electrode film 114 and the first amorphous silicon gate electrode film 115 are laminated, is formed on the p-well region. It should be noted that the first gate stack is formed in such a way that the first high dielectric-constant film 113, the first metal gate electrode film 114 and the first amorphous silicon gate electrode film 115 remain not only on the active regions 108 but also on the STI element isolation regions.

The first gate stack lithographic resist mask 117 is then removed, after which, as illustrated in FIGS. 12A, 12B and 12C, the second high dielectric-constant film 118, the second metal gate electrode film 119 and the second amorphous silicon gate electrode film 120 are successively laminated.

The second high dielectric-constant film 118 is an insulating film having a dielectric constant that is higher than that of the silicon dioxide (SiO₂) film, and an Al₂O₃ film can, for example, be used. The Al₂O₃ film can be formed by ALD.

The second metal gate electrode film 119 and the second amorphous silicon gate electrode film 120 can be formed using the same material and method as the first metal gate electrode film 114 and the first amorphous silicon gate electrode film 115.

Next, as illustrated in FIGS. 13A, 13B and 13C, a second gate stack lithographic resist mask 121 is formed in such a way as to cover the n-well regions. Then, the second amorphous silicon gate electrode film 120, the second metal gate electrode film 119 and the second high dielectric-constant film 118 that are not covered by the second gate stack lithographic resist mask 121 are successively removed by dry etching. By this means, a second gate stack, in which the first high dielectric-constant film 113, the second high dielectric-constant film 118, the second metal gate electrode film 119 and the second amorphous silicon gate electrode film 120 are laminated, is formed on the n-well region. It should be noted that the second gate stack is formed in such a way that the first high dielectric-constant film 113, the second high dielectric-constant film 118, the second metal gate electrode film 119 and the second amorphous silicon gate electrode film 120 remain not only on the active regions 109 but also on the STI element isolation regions. Further, the gap between the first gate stack and the second gate stack should be the gap necessary to remove the second amorphous silicon gate electrode film 120, the second metal gate electrode film 119 and the second high dielectric-constant film 118 formed on the first gate stack side surface.

The second gate stack lithographic resist mask 121 is then peeled off, after which the protective silicon dioxide film 116 remaining on the exposed first high dielectric-constant film 113 and the first gate stack is removed by wet etching, as illustrated in FIGS. 14A, 14B and 14C.

The third amorphous silicon gate electrode film 122 doped with phosphorus, the metal laminated film 123 and the hard mask silicon nitride film 124 are then successively formed, as illustrated in FIGS. 15A, 15B and 15C.

The third amorphous silicon gate electrode film 122 can be formed by LPCVD. The third amorphous silicon gate electrode film 122 is used as part of a gate electrode common to n-channel transistors formed in the p-wells and p-channel transistors formed in the n-wells, and is also used as a gate wiring line connected to thereto.

The metal laminated film 123 is formed by laminating a WSi film serving as an adhesive layer, a WN film serving as a barrier layer, and a W film. The WSi film can be formed by CVD, the WN layer can be formed by PVD or ALD, and the W film can be formed by PVD or CVD.

The hard mask silicon nitride film 124 can be formed by CVD. The hard mask silicon nitride film 124 is used as a hard mask during etching in the next step.

A resist mask (which is not shown in the drawings) having a desired pattern of gate structures and gate wiring lines is formed on the hard mask silicon nitride film 124, and the resist mask pattern is transferred to the hard mask silicon nitride film 124. Then, using a hard mask comprising the resist mask and the hard mask silicon nitride film 124, the exposed metal laminated film 123, third amorphous silicon gate electrode film 122, first and second amorphous silicon gate electrode films 115 and 120, first and second metal gate electrode films 114 and 119 and second high dielectric-constant film 118 are successively removed by dry etching, as illustrated in FIGS. 16A, 16B and 16C. The first high dielectric-constant film 113 and the lower-layer gate insulating film 112 are then removed by wet etching.

By means of the above process, the gate structures 151 including the gate insulating films (112, 113, 118), the gate electrodes (114, 115, 119, 120) and the gate wiring lines (122, 123) are formed.

The gate structures 151 obtained in this way are structures in which the high dielectric-constant films (113, 118) and the metal gate electrodes (114, 119) also remain on the STI element isolation regions, except in the vicinity of the boundaries between the p-type wells 110 and the n-type wells 111. However, a laminated construction comprising the flowable oxide film 106 and the silicon nitride film 107 is adopted in the STI element isolation regions. Then, as discussed hereinabove, the thickness of the flowable oxide film 106 in a location corresponding to the location of the upper surface of the semiconductor substrate 101 (the active regions) is made to be between 10 nm and 100 nm. In other words, the width of the flowable oxide film 106 sandwiched between the active regions 108 and 109 and the silicon nitride film 107 is only between 10 nm and 100 nm as seen in a plan view. Therefore the surface area over which the first high dielectric-constant film 113 is actually in contact with the flowable oxide film 106 is small. Therefore the amount of oxygen supplied from the STI element isolation regions to the high dielectric-constant films (113, 118) is small, and the phenomenon whereby oxygen spreads as far as the active regions 108 and 109 by way of the high dielectric-constant films (113, 118) and the metal gate electrode films (114, 119), causing the threshold of the transistor to shift, does not readily occur. Thus in this mode of embodiment, the amount of variation in the threshold voltage can be made to be substantially zero, and layout-dependent variations in the threshold can be eliminated. Moreover, the thickness of the silicon nitride film 107 in the STI element isolation regions is between ⅕ and ½ of the depth of the groove 104, and therefore no junction leakage or deterioration in the reliability of the transistor arise as a result of stress.

The offset spacers 125 are next formed, as illustrated in FIGS. 17A, 17B and 17C. Silicon nitride films or oxynitride films can be used as the offset spacers 125. The offset spacers 125 can be formed by using ALD, for example, to form a silicon nitride film or the like, and etching this film back.

Forming and halo-injection are then carried out for each of the n-channel and p-channel LDD regions 126.

The side wall spacers 127 are then formed. A silicon dioxide film can be used for the side wall spacers 127. The side wall spacers 127 can be formed by using LPCVD, for example, to form a silicon dioxide film, and etching this film back.

Each of the n-channel and p-channel S/D regions 128 is then formed by ion implantation.

Annealing is then performed to activate the impurities. Here, annealing performed at a high temperature for a short period of time, known as spike annealing, is carried out.

As discussed hereinabove, in this mode of embodiment the surface area of contact between the first high dielectric-constant film 113 and the oxide film which fills the STI isolation regions, in other words the flowable oxide film 106, is very small. Thus even if impurity activation annealing is performed, the amount of oxygen which spreads from the flowable oxide film 106 to the first high dielectric-constant film 113 is very small. Consequently there is substantially no variation in the thresholds of the transistors, and the thresholds can be accurately controlled.

The liner silicon nitride film 129 is then formed covering the entire surface, as illustrated in FIGS. 2A, 2B and 2C. The interlayer insulating film 130 is then formed as an SOD (Spin On Dielectric) film on the liner silicon nitride film 129. Further, the cap silicon dioxide film 131 is formed on the interlayer insulating film 130.

The connecting plugs 132 connected to the S/D regions 128, and the wiring lines 133 connected to the connecting plugs 132 are then formed. W can be used as the material for the connecting plugs 132 and the wiring lines 133.

The semiconductor device is subsequently completed by forming a protective film, for example, using known methods.

As described hereinabove, in this mode of embodiment the surface area of contact between the oxide films (flowable oxide films 106) filling the STI element isolation regions and the first high dielectric-constant films 113 formed on the STI element isolation regions is small. The amount of oxygen supplied from the flowable oxide film 106 to the first high dielectric-constant film 113 is therefore small, and the possibility that the threshold of the transistor will be caused to shift is low. The transistor threshold can thus be controlled accurately. Further, layout-dependency of the transistor threshold voltage can be substantially eliminated. Moreover, there are also no problems such as junction leakage or parasitic capacitance that arise when the entire STI element isolation region is filled by a silicon nitride film.

A semiconductor device according to a second mode of embodiment of the present invention will now be described. This mode of embodiment also assumes a case in which the semiconductor device is a DRAM.

FIG. 18 is a drawing illustrating the planar layout of part of a semiconductor device (a memory cell region) according to this mode of embodiment. Further, FIG. 18A is a cross-sectional view along the line A-N in FIG. 18. Further,

FIG. 19 is a cross-sectional view corresponding to part of the peripheral circuit portion of the semiconductor device according to this mode of embodiment.

Referring to FIG. 18, a plurality of first active regions AR1 which extend in the X1-direction, inclined approximately 30° to the right relative to the X-direction, and which are disposed repeatedly with an equal pitch in the Y-direction, and a plurality of second active regions AR2 which extend in the X2-direction, inclined approximately 30° to the left relative to the X-direction, and which are disposed repeatedly with an equal pitch in the Y-direction, are disposed repeatedly in the X-direction.

The active regions AR (AR1, AR2) are defined by forming element isolation regions in a semiconductor substrate. The element isolation regions are formed by filling grooves formed in the substrate with a flowable oxide film 202. In other words, the active regions AR are surrounded at their periphery by the flowable oxide films 202.

A plurality of bit lines 220 are disposed in such a way as to overlap a central portion of the first and second active regions AR1 and AR2 arranged in the X-direction. Further, a plurality of embedded gate electrodes (word lines) 205 are disposed in such a way as to pass through locations dividing into three each active region AR1 or AR2 arranged in the Y-direction.

End portions of the plurality of bit lines 220 are connected to a sense amplifier 300 contained in a peripheral circuit. Further, end portions of the plurality of gate electrodes 205 are connected to a sub-word driver 400 contained in a peripheral circuit.

A bit line diffusion layer 208 connected to a corresponding bit line 220 is formed in a central portion of each active region AR, in other words in a portion located between two embedded gate electrodes 205. Further, capacitor diffusion layers 207 are formed at both end portions of each active region AR. The capacitor diffusion layers 207 are connected to lower electrodes 225 of capacitors, which are storage elements.

Two cell transistors Tr1 and Tr2 are formed in each active region AR. In the two transistor regions Tr1 and Tr2, the capacitor diffusion layers 207 at the two ends of the active regions AR each serve as either the source region or the drain region. Further, the two transistors Tr1 and Tr2 share the bit line diffusion layer 208 as the other of the source region or the drain region.

Referring to FIG. 18A, STI grooves are formed on the obverse surface side of a p-type single-crystal silicon substrate (referred to hereinafter as ‘substrate’) 201, and these grooves are filled by flowable oxide films 202. The flowable oxide films 202 form the element isolation regions demarcating the active regions AR1 and AR2.

Two gate trenches 203 are formed in each active region AR. Gate insulating films 204 are formed on the inner surfaces of each gate trench 203. Further, the embedded gate electrodes 205 comprising a laminated film made from titanium nitride (TiN) 205a and tungsten (W) 205b are formed in such a way as to be in contact with the gate insulating films 204 and to fill lower portions of the gate trenches 203. Further, a cap insulating film 206 comprising a silicon nitride film is formed in contact with the upper surfaces of the embedded gate electrodes 205.

The capacitor diffusion layers 207, which will form the drain regions, are formed in the surface of the substrate 201 between the gate trenches 203 and the element isolation regions (flowable oxide films 202). Further, the bit line diffusion layers 208, which will form the source regions, are formed in the surface of the substrate 201 sandwiched between adjacent gate trenches 203.

A trench diffusion layer 209 is formed in the surface of the substrate 201 that is in contact with the bottom surface of each gate trench 203. The trench diffusion layers 209 that are adjacent to one another in a single active region AR are in a state in which they are connected to one another by means of the bit line diffusion layer 208 located therebetween.

A mask insulating film 210, comprising a silicon dioxide film used as a mask when the gate trenches 203 were formed, remains on the upper surfaces of the flowable oxide films 202 and the upper surface of the substrate 201 where the capacitor diffusion layers 207 have been formed. The cap insulating film 206 is formed in such a way as to cover the mask insulating film 210.

Bit line contact plugs 211 comprising a silicon film are provided penetrating through the cap insulating layer 206 and the mask insulating film 210 to reach the bit contact diffusion layers 208. The upper surfaces of the bit line contact plugs 211 are coplanar with the upper surface of the cap insulating film 206.

The bit lines 220 are formed in such a way as to pass above the bit line contact plugs 211, in contact with the upper surfaces thereof The bit lines 220 comprise a laminated film in which a plurality of films containing metal, for example, are laminated.

Cover insulating films 221 comprising a silicon nitride film are formed on the bit lines 220. Side-wall insulating films 222a comprising a silicon nitride film are formed on the sidewalls of the cover insulating films 221 and the bit lines 220.

A first interlayer insulating film 223 is formed in such a way as to cover the cover insulating films 221. A plurality of capacitor contact plugs 224 are formed penetrating through the first interlayer insulating film 223 to reach each of capacitor diffusion layers 207. The lower electrodes 225 of the capacitors are formed in contact with the upper surfaces of the capacitor contact plugs 224. A capacitative insulating film (which is not shown in the drawings) is formed over the entire surface, in such a way as to cover the lower electrodes 225, and an upper electrode 226 is formed in such a way as to cover the capacitative insulating film. A second interlayer insulating film 227 is formed on the upper electrode 226. A contact plug 228 is formed penetrating through the second interlayer insulating film 227 and connecting to the upper electrode 226. Upper wiring lines 229, including a wiring line connected to the contact plug 228 and other wiring lines, are formed on the second interlayer insulating film 227.

Referring to FIG. 19, STI grooves are formed on one surface side of the substrate 201, and the grooves are filled by the flowable oxide films 202 and silicon nitride films 251. The flowable oxide films 202 and the silicon nitride films 251 form the element isolation regions. Further, the element isolation regions define NMOS regions in which n-channel MOS (Metal-Oxide Semiconductor) transistors are formed, and PMOS regions in which p-channel MOS transistors are formed. The substrate 201 is p-type, and therefore n-type wells (NW) 252 are formed in the PMOS regions.

Lower-layer gate insulating films 253 are formed on the surface of the substrate 201 in each region. A first high dielectric-constant film 261, a first metal gate electrode film 262, a non-doped amorphous silicon gate electrode film 263, a phosphorus-doped amorphous silicon gate electrode film 211a, a metal laminated film 220a and a cover insulating film 221 are formed in a laminated manner on the lower-layer gate insulating films 253 in the NMOS regions. This laminated construction 270a has the same structure as the gate structure 151 in the n-channel transistor region in the first mode of embodiment.

Further, the first high dielectric-constant film 261, a second high dielectric-constant film 265, a second metal gate electrode film 266, an amorphous silicon gate electrode film 267, the phosphorus-doped amorphous silicon gate electrode film 211a, the metal laminated film 220a and the cover insulating film 221 are formed in a laminated manner on the lower-layer gate insulating films 253 in the PMOS regions. This laminated construction 270b has the same structure as the gate structure 151 in the p-channel transistor region in the first mode of embodiment.

Side-wall insulating films 222b comprising a silicon nitride film are formed on the sidewalls of the laminated structures 270a and 270b.

Source/drain diffusion layers 281a containing an n-type impurity are formed in the surface of the substrate 201 in the NMOS regions, forming planar n-channel MOS transistors. Further, source/drain diffusion layers 281b containing a p-type impurity are formed in the surface of the substrate 201 in the PMOS regions, forming planar p-channel MOS transistors.

The first interlayer insulating film 223 is formed in such a way as to cover the cover insulating films 221. Contact plugs 224a are formed penetrating through the first interlayer insulating film 223 and connecting to each of the source/drain diffusion layers 281a and 281b. Further, wiring lines 225a are formed on the first interlayer insulating film 223 in such a way as to be connected to the contact plugs 224a. A third interlayer insulating film 227a is formed in such a way as to cover the wiring lines 225a. Contact plugs 228a are formed penetrating through the third interlayer insulating film 227a to reach the wiring lines 225a. Upper wiring lines 229a are formed in such a way as to be connected to the contact plugs 228a.

A detailed description of the method of manufacturing the semiconductor device configured as discussed hereinabove is omitted. It should be noted that in FIG. 18A and FIG. 19, the same reference numbers are assigned to films and the like that are formed at the same time, and in the case of films or the like that are formed at the same time but have different functions or the like, these are distinguished by appending a letter to the reference code.

In the semiconductor device according to this mode of embodiment, the element isolation regions in the peripheral circuit portion illustrated in FIG. 19 are filled by the flowable oxide films 202 and the silicon nitride films 251 in the same way as in the first mode of embodiment. The flowable oxide films 202 cover the sidewall surfaces of the STI grooves in the peripheral circuit portion, and fill the grooves to between ½ and ⅘ of the groove depth. The silicon nitride films 251 fill the remaining spaces in the grooves (the upper portions). The distance between the silicon nitride film 251 and the active region in a location at the surface of the semiconductor substrate is between 10 and 100 nm.

The flowable oxide films 202 are formed at the same time in the memory region (FIG. 18A) and the peripheral region (FIG. 19). The width of the STI grooves (first grooves) in the memory region is less than the width of the STI grooves (second grooves) in the peripheral region. Therefore the flowable oxide films 202 completely fill the STI grooves in the memory region during the period in which the lower portions of the STI grooves in the peripheral region are being filled. Because the flowable oxide film 202 is flowable during film deposition, the grooves can be completely filled without the generation of voids, even if the width of the STI groove is small and the aspect ratio is large.

The same advantages are obtained in this mode of embodiment as in the first mode of embodiment.

Several modes of embodiment of the present invention have been described hereinabove, but various variations and modifications may be made without deviating from the gist of the present invention, without limitation to the abovementioned modes of embodiment of the present invention.

This application is based upon and claims the benefit of priority from Japanese Patent Application No. 2012-262021, filed on Nov. 30, 2012, the entire disclosure of which is incorporated herein by reference.

### EXPLANATION OF THE REFERENCE NUMBERS

101 Semiconductor substrate
102 Pad silicon dioxide film
103 Hard mask silicon nitride film
104 Groove
105 Pad silicon dioxide film
106 Flowable oxide film
107 Silicon nitride film
108, 109 Active region
110 p-type well
111 n-type well
112 Lower-layer gate insulating film
113 First high dielectric-constant film
114 First metal gate electrode film
115 First amorphous silicon gate electrode film
116 Protective silicon dioxide film
117 First gate stack lithographic resist mask
118 Second high dielectric-constant film
119 Second metal gate electrode film
120 Second amorphous silicon gate electrode film
121 Second gate stack lithographic resist mask
122 Third amorphous silicon gate electrode film
123 Metal laminated film
124 Hard mask silicon nitride film
125 Offset spacer
126 LDD region
127 Side wall spacer
128 S/D region
129 Liner silicon nitride film
130 Interlayer insulating film
131 Cap silicon dioxide film
132 Connecting plug
133 Wiring line
151 Gate structure
201 p-type single-crystal silicon substrate
202 Flowable oxide film
203 Gate trench
204 Gate insulating film
205 Gate electrode
205a Titanium nitride
205b Tungsten
206 Cap insulating film
207 Capacitor diffusion layer
208 Bit line diffusion layer
209 Trench diffusion layer
210 Mask insulating film
211 Bit line contact plug
211 a Phosphorus-doped amorphous silicon gate electrode film
220 Bit line
220a Metal laminated film
221 Cover insulating film
222a, 222b Side-wall insulating film
223 First interlayer insulating film
224 Capacitor contact plug
224a Contact plug
225 Lower electrode
225a Wiring line
226 Upper electrode
227 Second interlayer insulating film
227a Third interlayer insulating film
228, 228a Contact plug
229, 229a Upper wiring line
251 Silicon nitride film
252 n-type well
253 Lower-layer gate insulating film
261 First high dielectric-constant film
262 First metal gate electrode film
263 Non-doped amorphous silicon gate electrode film
265 Second high dielectric-constant film
266 Second metal gate electrode film
267 Amorphous silicon gate electrode film
270a, 270b Laminated structure
281a, 281b Source/drain diffusion layer

1. A device comprising:
a gate structure, formed by successively laminating an insulating film having a high dielectric constant and an electrode film containing a metal material onto a substrate demarcated into an active region and an element isolation region surrounding the active region, extends across the element isolation region from the active region, wherein the element isolation region comprises:
a groove formed in the substrate;
a first insulating film which covers sidewall surfaces of the groove and fills a lower portion of the groove; and
a second insulating film which covers the first insulating film filling the lower portion of the groove, and which fills an upper portion of the groove.

2. The device of claim 1, wherein the width of the first insulating film sandwiched between the active region and the second insulating film is between 10 nm and 100 nm as seen in a plan view.

3. The device of claim 1, wherein the second insulating film does not contain oxygen.

4. The device of claim 3, wherein the second insulating film is a silicon nitride film.

5. The device of claim 3, wherein the first insulating film contains both silicon and oxygen.

6. The device of claim 5, wherein the first insulating film is a flowable chemical vapor deposition (“FCVD”) film.

7. The device of claim 5, comprising a part in which the thickness of the first insulating film covering the sidewall surfaces of the groove gradually increases from the upper portion of the groove toward a bottom portion thereof.

8. The device of claim 1, wherein the first insulating film fills between ½ and ⅘ of the depth of the groove.

9. A device comprising characterized in that it comprises:
a substrate demarcated into a memory cell region and a peripheral circuit region;
a first element isolation region defined in the memory cell region and including a first groove;
an active region defined in the peripheral circuit region;
a second element isolation region defined in the peripheral circuit region and including a second groove surrounding the active region;
a first insulating film including a first part filling the first groove, and a second part which covers sidewall surfaces of the second groove and fills a lower portion of the second groove;
a second insulating film which covers the first insulating film filling the lower portion of the second groove, and which fills an upper portion of the second groove; and
a gate structure which is formed by successively laminating onto the substrate an insulating film having a high dielectric constant and an electrode film containing a metal material, and which extends across the second element isolation region from the active region.

10. The device of claim 9, wherein the first insulating film is a flowable chemical vapor deposition (“FCVD”) film.

11. The device of claim 9, wherein the first insulating film contains both silicon and oxygen, and the second insulating film does not contain oxygen.

12. The device of claim 9, wherein the width of the first insulating film sandwiched between the active region and the second insulating film is between 10 nm and 100 nm as seen in a plan view.

13. A method of manufacturing a device, comprising:
forming a stopper film on a substrate;
patterning the stopper film and forming a groove in the substrate;
using flowable chemical vapor deposition (“FCVD”) to form a first insulating film which covers sidewall surfaces of the groove and fills a lower portion of the groove;
forming a second insulating film which covers the first insulating film and fills an upper portion of the groove;
carrying out polishing in such a way that the respective upper surfaces of the stopper film and the second insulating film form a substantially flat surface;
removing the stopper film;
forming a gate insulating film having a high dielectric constant; and
forming a gate electrode containing a metal material covering the gate insulating film.

14. The method of claim 13, comprising forming the first insulating film set in such a way that the width of the first insulating film sandwiched between the substrate and the second insulating film is between 10 nm and 100 nm as seen in a plan view.

15. The method of claim 13, wherein:
a first groove and a second groove which is wider than said first groove are formed as the groove; and
forming the first insulating film comprising completely filling the first groove, and filling a lower portion of the second groove.

16. The method of claim 13, wherein forming the first insulating film comprises out using FCVD.

17. The method of claim 13, wherein the first insulating film is a film containing both silicon and oxygen, and the second insulating film is a film that does not contain oxygen.
